(19) United States
(12) Patent Application Publication
(10) Pub. No.: US 2024/0021671 A1
(43) Pub. Date: Jan. 18, 2024

(54) EPITAXIAL STRUCTURE OF SEMICONDUCTOR DEVICE, DEVICE AND METHOD OF MANUFACTURING EPITAXIAL STRUCTURE

(71) Applicant: DYNAX SEMICONDUCTOR, INC., Kunshan (CN)

(72) Inventors: Hui ZHANG, Kunshan (CN); Kewei TAN, Kunshan (CN); Susu KONG, Kunshan (CN); Shiqiang LI, Kunshan (CN); Wenlong Zhou, Kunshan (CN); Xiaoqing DU, Kunshan (CN)

(21) Appl. No.: 18/268,537

(22) PCT Filed: Dec. 21, 2021
(86) PCT No.: PCT/CN2021/140112

§ 371 Date: Jun. 20, 2023

(30) Foreign Application Priority Data
Dec. 24, 2020 (CN) 202011573138.2

(51) Int. Cl. H01L 29/06; H01L 29/20; H01L 29/778; H01L 21/02; C30B 25/18

(52) U.S. Cl. CPC H01L 29/0638; H01L 29/2003; H01L 29/7786; H01L 21/02458; H01L 21/02505; H01L 21/0254; C30B 25/183

(57) ABSTRACT

The present disclosure relates to an epitaxial structure of a semiconductor device, a device, and a method of manufacturing the epitaxial structure. The epitaxial structure includes a substrate, and a first semiconductor layer, located on the substrate, the first semiconductor layer including buffer layers, the buffer layers at least including a first buffer layer, a second buffer layer, and a third buffer layer which are arranged in layers, and the second buffer layer being located between the first buffer layer and the third buffer layer, wherein the second buffer layer is doped with iron impurities, and the first buffer layer and the third buffer layer are not actively doped with iron impurities, and concentration of iron impurities of the second buffer layer satisfies a first preset range.

### CROSS REFERENCE TO RELATED APPLICATIONS

This patent application is a National Stage Entry of PCT/CN2021/140112 filed on Dec. 21, 2021, which claims the benefit and priority of Chinese Patent Application No. 202011573138.2 filed on Dec. 24, 2020, the disclosures of which are incorporated by reference herein in their entirety as part of the present application.

### BACKGROUND

The present disclosure relates to a field of semiconductor technology, and particularly relates to an epitaxial structure of a semiconductor device, a device, and a method of manufacturing the epitaxial structure.

Due to the characteristics of large forbidden band width, high electron mobility, high breakdown field strength, good thermal conductivity and strong spontaneous and piezoelectric polarization effects, the semiconductor material gallium nitride (GaN) is more suitable for manufacturing high frequency, high voltage and high temperature resistant high power electronic devices comparing with the first generation semiconductor materials and the second generation semiconductor materials, especially in the fields of radio frequency and power supply.

In a gallium nitride high electron mobility transistor (GaN HEMT) structure, in order to obtain better device leakage characteristics as well as pinch off characteristics, it is usually necessary to set the buffer layer to be a high resistance. It is extremely difficult to achieve high resistance for intrinsic GaN materials in the process, but the high resistance of the buffer layer can be achieved by introducing acceptor impurities during the growth process of the buffer layer. Commonly used acceptor impurities include carbon (C) atoms or iron (Fe) atoms.

The deep-level traps formed by doping can affect the crystal quality of the buffer layer as well as the sub-threshold characteristics of the device while capturing the buffer layer electrons to obtain high resistance.

### BRIEF DESCRIPTION

On that account, it is necessary to provide an improved epitaxial structure of a semiconductor device for the problem that it is difficult to take into account the crystal quality and the sub-threshold characteristics of the device when manufacturing a high resistance buffer layer in traditional semiconductor materials.

An epitaxial structure of a semiconductor device includes a substrate, and a first semiconductor layer, located on the substrate, the first semiconductor layer including buffer layers, the buffer layers at least including a first buffer layer, a second buffer layer, and a third buffer layer which are arranged in layers, and the second buffer layer being located between the first buffer layer and the third buffer layer, wherein, the second buffer layer is doped with iron impurities, and the first buffer layer and the third buffer layer are not actively doped with iron impurities, and concentration of iron impurities of the second buffer layer satisfies a first preset range.

In the above-mentioned epitaxial structure of a semiconductor device, the buffer layers thereof at least include a first buffer layer, a second buffer layer, and a third buffer layer, the second buffer layer is doped with iron impurities, and the first buffer layer and the third buffer layer are not actively doped with iron impurities, and concentration of iron impurities of the second buffer layer satisfies a first preset range, so that on the one hand, this helps to achieve a high resistance of the buffer layers such that the device obtains better leakage and pinch-off characteristics, and on the other hand, in the above epitaxial structure, iron impurities are distributed in a suitable concentration range in the buffer layer in the middle, while the buffer layers near the substrate and the second semiconductor layer have almost no or only very little iron impurities; specifically, for instance, concentration of iron impurities in the first buffer layer is substantially 0, and concentration of iron impurities in the third buffer layer is less than 10 16 cm -3 , may be substantially 0, thereby helping to improve the crystal quality of the buffer layers, and at the same time, this also helps to improve the drain induced barrier lowering (DIBL) effect of the device and trailing effect of the iron impurities, which thus may improve the sub-threshold characteristics of the device and ensure the reliability of the device.

In an embodiment, the second buffer layer is further doped with carbon impurities, concentration of carbon impurities of the second buffer layer satisfies a second preset range, and the concentration of carbon impurities of the second buffer layer is less than concentration of iron impurities of the second buffer layer.

In an embodiment, the first preset range is 10¹⁶ cm⁻³˜5×10¹⁸ cm⁻³, and the second preset range is 10¹⁶ cm⁻³˜10¹⁷ cm⁻³.

In an embodiment, thickness of the second buffer layer is ^{d}^{₂}, wherein 200 nm≤^{d}^{₂}≤800 nm.

In an embodiment, the first buffer layer is located on a side of the second buffer layer close to the substrate, and the third buffer layer is located on a side of the second buffer layer close to a second semiconductor layer, wherein the first buffer layer has carbon impurities, and concentration of carbon impurities of the first buffer layer is less than or equal to the concentration of carbon impurities of the second buffer layer, and, the third buffer layer has carbon impurities, and concentration of carbon impurities of the third buffer layer is less than the concentration of carbon impurities of the second buffer layer.

In an embodiment, the concentration of carbon impurities of the first buffer layer is less than or equal to 10¹⁷ cm⁻³, the concentration of carbon impurities of the second buffer layer is greater than or equal to 10¹⁶ cm⁻³ and less than or equal to 10¹⁷ cm⁻³, and the concentration of carbon impurities of the third buffer layer is less than or equal to 5×10¹⁶ cm⁻³.

In an embodiment, thickness of the third buffer layer is ^{d}^{₃}, wherein 200 nm≤^{d}^{₃}≤500 nm.

In an embodiment, thickness of the first buffer layer is ^{d}^{₂}, wherein 200 nm≤^{d}^{₁}≤800 nm.

In an embodiment, the first semiconductor layer further includes a nucleation layer, the nucleation layer is located on the substrate, and the buffer layer is located on a side of the nucleation layer away from the substrate.

In an embodiment, the second semiconductor layer includes a channel layer, located on a side of the first semiconductor layer away from the substrate, a potential barrier layer, located on a side of the channel layer away from the first semiconductor layer, the potential barrier layer and the channel layer forming a heterojunction structure, and forming a conductive channel at a hetero interface, and a cap layer, located on a side of the potential barrier layer away from the channel layer.

The present disclosure further provides a semiconductor device.

A semiconductor device includes the above-mentioned epitaxial structure.

The above-mentioned semiconductor device may be manufactured by the aforementioned epitaxial structure, thereby helping to obtain better leakage and pinch-off characteristics of the device, improving the sub-threshold characteristics of the device, and ensuring the reliability of the device.

The present disclosure further provides a method of manufacturing an epitaxial structure of a semiconductor device.

A method of manufacturing an epitaxial structure of a semiconductor device, includes providing a substrate, forming a first semiconductor layer on the substrate, the first semiconductor layer including buffer layers, the buffer layers at least including a first buffer layer, a second buffer layer, and a third buffer layer which are arranged in layers, and the second buffer layer being located between the first buffer layer and the third buffer layer, wherein the second buffer layer is doped with iron impurities, and the first buffer layer and the third buffer layer are not actively doped with iron impurities, and concentration of iron impurities of the second buffer layer satisfies a first preset range, and forming a second semiconductor layer on a side of the first semiconductor layer away from the substrate, wherein a conductive channel is formed in the second semiconductor layer.

In the above-mentioned method of manufacturing, in forming the buffer layers, the first buffer layer, the second buffer layer, and the third buffer layer may be formed in three stages, and the iron impurities are doped in the second buffer layer, and the concentration of iron impurities of the second buffer layer is made to satisfy the first preset range, so that on the one hand, this helps to achieve a high resistance of the buffer layers such that the device obtains better leakage and pinch-off characteristics, and on the other hand, iron impurities are distributed in a suitable concentration range in the buffer layer in the middle, while the buffer layers near the substrate and the second semiconductor layer have almost no or only very little iron impurities; specifically, for instance, concentration of iron impurities in the first buffer layer is substantially 0, and concentration of iron impurities in the third buffer layer is less than 10¹⁶ cm⁻³, may be substantially 0, helping to improve the crystal quality of the buffer layers, and at the same time, this also helps to improve the drain induced barrier lowering (DIBL) effect of the device and trailing effect of the iron impurities, which thus may improve the sub-threshold characteristics of the device and ensure the reliability of the device.

In an embodiment, forming a first semiconductor layer on the substrate includes epitaxially growing a nucleation layer on the substrate, epitaxially growing the first buffer layer on a side of the nucleation layer away from the substrate, epitaxially growing the second buffer layer on a side of the first buffer layer away from the nucleation layer, while co-doping iron impurities and carbon impurities into the second buffer layer, wherein concentration of carbon impurities of the second buffer layer satisfies a second preset range, and the concentration of carbon impurities of the second buffer layer is less than the concentration of iron impurities of the second buffer layer, and epitaxially growing the third buffer layer on a side of the second buffer layer away from the first buffer layer.

In an embodiment, the first buffer layer has carbon impurities, and epitaxially growing the second buffer layer on a side of the first buffer layer away from the nucleation layer includes forming the second buffer layer by using an epitaxial process while controlling the concentration of carbon impurities of the second buffer layer to be greater than or equal to the concentration of carbon impurities of the first buffer layer, and the third buffer layer has carbon impurities, and epitaxially growing the third buffer layer on a side of the second buffer layer away from the first buffer layer includes forming the third buffer layer by using an epitaxial process while controlling the concentration of carbon impurities of the third buffer layer to be less than the concentration of carbon impurities of the second buffer layer.

In an embodiment, steps of forming the buffer layers include turning off an iron source when the first buffer layer is formed, so that the concentration of iron impurities in the first buffer layer is substantially 0, turning on the iron source and controlling a flow rate when the second buffer layer is formed so that the concentration of iron impurities in the second buffer layer is 10¹⁶ cm⁻³˜5×10¹⁸ cm⁻³, and turning off the iron source when the third buffer layer is formed, so that the concentration of iron impurities in the third buffer layer is less than 10¹⁶ cm⁻³.

### BRIEF DESCRIPTION OF THE DRAWINGS

FIG. 1 is a schematic structural view of an embodiment of the present disclosure;

FIG. 2 is a schematic diagram of the concentration distribution of carbon impurities and iron impurities in the epitaxial structure of the present disclosure; and

FIG. 3 is a schematic structural view of buffer layers of another embodiment of the present disclosure.

### DETAILED DESCRIPTION

In order to facilitate the understanding of the present disclosure, the present disclosure will be described more fully hereinafter with reference to the accompanying drawings. Implementations of the disclosure are given in the accompanying drawings. However, the present disclosure can be embodied in many different forms and is not limited to the implementations set forth herein. Rather, these implementations are provided so that the disclosed content of the present disclosure will be more thoroughly and completely understood.

It should be noted that when an element is referred to as being “fixed” to another element, it may be directly on the other element or there may also be an intermediate element. When an element is considered to be “connected” to another element, it may be directly connected to the other element or there may also be an intermediate element. The terms “vertical”, “horizontal”, “left”, “right”, “upper”, “lower”, “front”, “rear”, “circumferential” and similar expressions used herein are based on the orientation or positional relationships shown in the accompanying drawings and are intended only to facilitate and simplify the description of the present disclosure, not to indicate or imply that the device or element referred to must have a particular orientation, be constructed and operate in a particular orientation, and therefore are not to be construed as limiting the present disclosure.

Unless otherwise defined, all technical and scientific terms used herein have the same meaning as commonly understood by those skilled in the art to which the present disclosure belongs. The terms used herein in the description of the present disclosure are for the purpose of describing specific embodiments only and are not intended to limit the present disclosure. The term “and/or” as used herein includes any and all combinations of one or more of the relevant listed items.

In order to obtain better device leakage and pinch-off characteristics, high resistance buffer layers are required in semiconductor devices. In conventional processes, this can be achieved by introducing acceptor impurities during the growth process of the buffer layers. However, the higher concentration of acceptor impurities in the buffer layers affects the crystal quality of the buffer layers and the sub-threshold characteristics of the device, which leads to the poor reliability of the device and limits the application range of the device.

Therefore, in order to solve the problem in the prior art and achieve the satisfaction of the high resistance of the buffer layers while reducing the effect of doping on the crystal quality of the buffer layers as well as the sub-threshold characteristics of the device, the present disclosure provides a novel epitaxial structure of a semiconductor device. The technical solution of the present disclosure will be described in detail by specific implementations below.

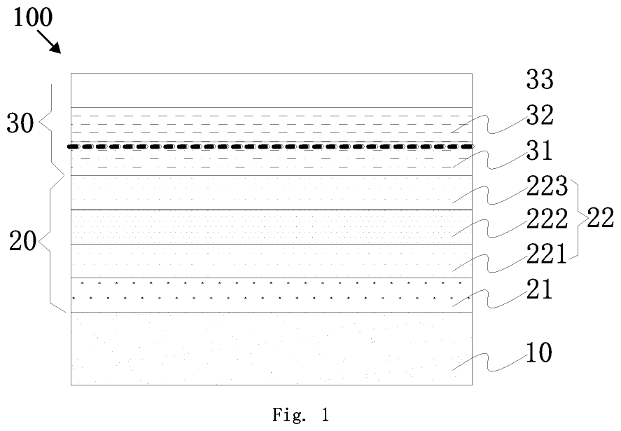

Referring to FIG. 1, the present disclosure provides an epitaxial structure 100 of a semiconductor device, including a substrate 10 and a first semiconductor layer 20 being located on the substrate 10. The substrate 10 may be a combination of one or more of gallium nitride, aluminum gallium nitride, indium gallium nitride, aluminum indium gallium nitride, indium phosphide, gallium arsenide, silicon carbide, diamond, sapphire, germanium, silicon, or any other material capable of growing group III nitrides.

Specifically, the first semiconductor layer 20 includes buffer layers 22 which include at least a first buffer layer 221, a second buffer layer 222, and a third buffer layer 223 which are arranged in layers, the second buffer layer 222 being located between the first buffer layer 221 and the third buffer layer 223. It can be understood that the first buffer layer 221 may be located between the substrate 10 and the second buffer layer 222, or may be located on a side of the second buffer layer 222 away from the substrate 10. Taking FIG. 1 as an example, the first buffer layer 221 is located between the substrate 10 and the second buffer layer 222, and the third buffer layer 223 is located on a side of the second buffer layer 222 away from the substrate

The buffer layer 22 may play a role of bonding the layer of semiconductor material to be grown next, and may protect the substrate 10 from intrusion by some metal ions. The buffer layer 22 may be a group III nitride material such as AlGaN, GaN, or AlGaInN.

Further, the second buffer layer 222 is doped with iron impurities, and the first buffer layer 221 and the third buffer layer 223 are not actively doped with iron. Taking FIG. 1 as an example, the iron impurities in the buffer layers 22 may be distributed in the second buffer layer 222. The content of iron impurities in the first buffer layer 221 is substantially 0, and the content of iron impurities in the third buffer layer 223 may also be substantially 0. However, due to the tailing effect of iron impurities of the second buffer layer, there will be a small part of iron impurities distributed in the third buffer layer, but the content thereof is extremely small, less than 10¹⁶ cm⁻³. In addition, with the advancement of technology, if the tailing effect can be eliminated, it is preferable that the iron impurity in the third buffer layer is also substantially 0. In the present disclosure, the content of iron impurities is substantially 0 means that iron is not actively doped, and theoretically content of iron impurities is 0, but in practice iron will inevitably be present.

The iron impurities of the buffer layers 22 are distributed in the second buffer layer 222 located in the middle layer, and the main material of the adjacent layer in contact with the second buffer layer 222 where the iron impurities are distributed is the same as the main material of the second buffer layer 222. In other words, the iron impurities of the buffer layers 22 do not directly contact the semiconductor layers with different main materials such as the substrate, nucleation layer or channel layer, etc.

The semiconductor epitaxial structure may also include a second semiconductor layer 30, located on a side of the first semiconductor layer 20 away from the substrate, and the second semiconductor layer 30 has a conductive channel formed therein. As shown in FIG. 1, the conductive channel is illustrated by a thick dashed line. Specifically, the second semiconductor layer 30 may include a channel layer 31, and a potential barrier layer 32. The channel layer 31 may be formed between the buffer layers 22 and the potential barrier layer 32, may form a heterojunction structure together with the potential barrier layer 32 above it, and forms a two-dimensional electron gas channel (i.e., a conductive channel) at the interface. The channel layer 31 provides a channel for two-dimensional electron gas movement, and the potential barrier layer 32 acts as a potential barrier. The potential barrier layer 32 may be an AlₓGa₁₋ₓN material, where the Al content x may be controlled between 0 and 1.

Specifically, the first buffer layer 221, the second buffer layer 222, and the third buffer layer 223 may be formed sequentially in stages by an epitaxial growth process. During the formation of the first buffer layer 221, the growth conditions are controlled and the iron source is turned off so that the content of iron impurities in the first buffer layer 221 may be 0, during the formation of the second buffer layer 222, the growth conditions are adjusted and the iron source is turned on to control the flow rate so that iron impurities are doped into the second buffer layer 222, and during the formation of the third buffer layer 223, it continues adjusting the growth conditions and turning off the iron source, so that the concentration of iron impurities attenuating into the conductive channel can be reduced, such that the concentration of iron impurities of the third buffer layer 223 is maintained in a low range, such as less than 10¹⁶ cm⁻³. The distribution of iron impurities in the second buffer layer 222 may be achieved in the above manner, and it should be understood that the first buffer layer 221, second buffer layer 222, and third buffer layer 223 required may also be formed by other growth processes, and the present application does not limit the specific forming process of buffer layers 22.

The epitaxial structure 100 of the semiconductor device described above has buffer layers 22 including at least a first buffer layer 221, a second buffer layer 222, and a third buffer layer 223, the buffer layer 22 being doped with iron impurities being distributed in the second buffer layer 222, where the concentration of iron impurities of the second buffer layer 222 satisfies a first preset range, so that on the one hand, this helps to achieve a high resistance of the buffer layers 22 such that the device obtains better leakage and pinch-off characteristics, and on the other hand, in the above epitaxial structure 100, iron impurities are distributed in a suitable concentration range in the buffer layer in the middle, while the buffer layers near the substrate and the second semiconductor layer have almost no or only very little iron impurities; specifically, for instance, concentration of iron impurities in the first buffer layer is substantially 0, and concentration of iron impurities in the third buffer layer is less than 10¹⁶ cm⁻³, may be substantially 0, thereby helping to improve the crystal quality of the buffer layers 22, and at the same time, this also helps to improve the drain induced barrier lowering (DIBL) effect of the device and trailing effect of the iron impurities, which thus may improve the sub-threshold characteristics of the device and ensure the reliability of the device. Taking the epitaxial structure as shown in FIG. 1 as an example, the first buffer layer 221 has almost no iron impurities, which can effectively improve the leakage induction barrier reduction effect of the device while enhancing the crystal growth quality of the buffer layer 22. Moreover, the second buffer layer 222 and the second semiconductor layer 30 are separated by a third buffer layer 223, and the concentration of iron impurities in the third buffer layer 223 is also extremely low, which helps to reduce the iron content attenuating into the channel, avoiding the impurity scattering caused by iron impurities entering the channel and reducing the two-dimensional electron gas concentration and electron mobility, affecting the saturation current and output power of the device.

In the exemplary implementation, the second buffer layer 222 is further doped with carbon impurities, concentration of carbon impurities of the second buffer layer 222 satisfies a second preset range, and the concentration of carbon impurities of the second buffer layer 222 is less than the concentration of iron impurities of the second buffer layer 222.

Specifically, to obtain a better crystal quality, the crystal growth can be performed by an epitaxial growth process at high temperature and pressure, under this growth condition, the concentration of carbon impurities in the second buffer layer 222 will not be very high, while the concentration of iron impurities is less affected by temperature and pressure because the iron impurities are doped by flow control, and thus the iron impurities can be used as the main acceptor impurities to achieve high resistance of the buffer layers 22. On the other hand, considering that the concentration of carbon impurities is easily affected by temperature and pressure, the second buffer layer 222 may continue to be doped with a suitable concentration of carbon impurities to compensate for the high resistance achieving effect of iron impurities, and thus obtain the desired high resistance of the buffer layers.

Further, the first preset range of the concentration of iron impurities in the second buffer layer 222 is 10¹⁶ cm⁻³5×10¹⁸ cm⁻³ and the second preset range of the concentration of carbon impurities in the second buffer layer 222 is 10¹⁶ cm⁻³˜10¹⁷ cm⁻³ . Iron impurities and carbon impurities, as deep energy level acceptors, are co-doped in the second buffer layer 222 at a suitable concentration, which can serve to high resistance and reduce the leakage of the whole buffer layers 22. If the concentration of iron impurities is too low, the desired high resistance of the buffer layers cannot be achieved. If the concentration of iron impurities is too high and the concentration of carbon impurities is too low, the crystal quality and surface morphology of the buffer layer 22 will be affected, and if the concentration of carbon impurities is too high, the quality of the buffer layer crystal growth will deteriorate.

In the exemplary implementation, as shown in FIG. 1, the first buffer layer 221 is located on a side of the second buffer layer 222 close to the substrate 10, and the third buffer layer 223 is located on a side of the second buffer layer 222 close to the second semiconductor layer 30. Further, as shown in FIG. 2, the first buffer layer 221 has carbon impurities, and the concentration of carbon impurities of the first buffer layer 221 is less than or equal to the concentration of carbon impurities of the second buffer layer 222. Moreover, the third buffer layer 223 has carbon impurities, and the concentration of carbon impurities of the third buffer layer 223 is less than the concentration of carbon impurities of the second buffer layer 222. By controlling that the concentrations of carbon impurities of both the first buffer layer 221 and the third buffer layer 223 are less than the concentration of carbon impurities of the second buffer layer 222, the crystal quality of the buffer layers 22 may be effectively improved while achieving a high resistance. On the other hand, since the concentration of carbon impurities of the third buffer layer 223 is easier to adjust, the crystal quality of the buffer layers 22 may be further improved by controlling the concentration of carbon impurities of the third buffer layer 223 to be less than that of the second buffer layer 222.

Further, the concentration of carbon impurities of the first buffer layer 221 is less than or equal to 10¹⁷ cm⁻³, the concentration of carbon impurities of the second buffer layer 222 is greater than or equal to 10¹⁶ cm⁻³ and less than or equal to 10¹⁷ cm⁻³, and the concentration of carbon impurities of the third buffer layer 223 is less than or equal to 5×10¹⁶ cm⁻³. Controlling the concentrations of carbon impurities of the first buffer layer 221, the second buffer layer 222, and the third buffer layer 223 to meet the above ranges, respectively, is conducive to achieving high resistance of the buffer layers 22 and improving the crystal quality of the buffer layers 22. Moreover, when the concentration of carbon impurities of each buffer layer is too high, it will significantly reduce the crystal quality of buffer layers 22, while when the concentration of carbon impurities of the second buffer layer 222 is too low, it will not be able to better compensate for the effect of achieving high resistance of iron impurities.

In the exemplary implementation, continuing referring to FIG. 1, the thickness of the third buffer layer 223 is ^{d}^{₃}, wherein 200 nm≤^{d}^{₃}≤500 nm. Controlling the thickness of the third buffer layer 223 to meet the above relationship can make the iron impurities in the second buffer layer 222 have a proper distance from the conductive channel, which can reduce the impact of the doped iron impurities on the two-dimensional electron gas in the conductive channel. Moreover, when the third buffer layer 223 is too thin, the distance between the iron impurities in the second buffer layer 222 and the conductive channel is too small, which may easily lead to an excessive amount of iron impurities attenuating into the conductive channel, which in turn affects the saturation current and output power of the device, and it is difficult to ensure the reliability of the device. Moreover, when the third buffer layer 223 is too thick, it affects the growth efficiency of the buffer layers 22.

In the exemplary implementation, thickness of the second

buffer layer 222 is ^{d}^{₂}, wherein 200 nm≤^{d}^{₂}≤800 nm. Controlling the thickness of the second buffer layer 222 to satisfy the above relationship can better achieve high resistance of the buffer layers 22 and improve the crystal quality of the buffer layers 22. Moreover, when the second buffer layer 222 is too thin, it will affect achieving of high resistance of the whole buffer layers 22, and when the second buffer layer 222 is too thick, it will affect the growth efficiency of the buffer layers 22. Moreover, the second buffer layer 222 is further doped with a higher concentration of iron impurities, which will also affect the crystal quality and surface morphology of the second buffer layer 22 if the second buffer layer 222 is too thick.

In the exemplary implementation, the thickness of the first buffer layer is ^{d}^{₁}, wherein 200 nm≤^{d}^{₁}≤800 nm. Controlling the thickness of the first buffer layer 221 to satisfy the above relationship is conducive to enable the crystal of the first buffer layer 221 to convert from three-dimensional growth to two-dimensional growth in time to ensure the crystal growth quality of the subsequent buffer layers and does not affect the growth efficiency of the buffer layers 22. Moreover, when the first buffer layer 221 is too thin, it is highly likely that the three-dimensional growth of the first buffer layer 221 will not be converted to two-dimensional growth in time, resulting in poor quality of the subsequent buffer layer growth. Moreover, when the first buffer layer 221 is too thick, it will affect the growth efficiency of the buffer layers 22.

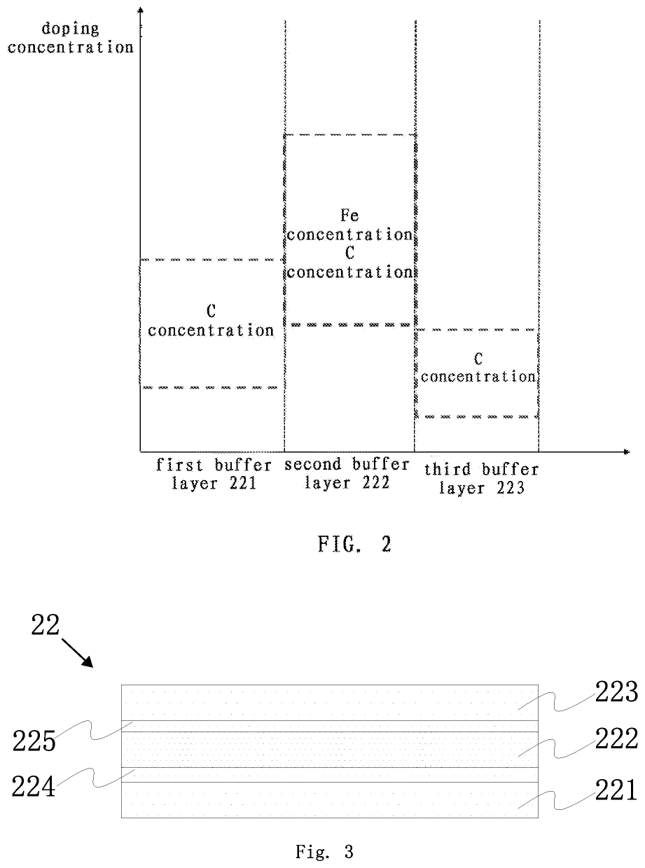

In the exemplary implementation, referring to FIG. 3, the buffer layers 22 may further include a fourth buffer layer 224 and a fifth buffer layer 225. Specifically, the fourth buffer layer 224 is located between the first buffer layer 221 and the second buffer layer 222, and the fifth buffer layer 225 is located between the second buffer layer 222 and the third buffer layer 223. When the first buffer layer 221 is too thin, the fourth buffer layer 224 may be used to compensate for the thickness of the first buffer layer 221, when the third buffer layer 221 is too thin, the fifth buffer layer 225 may be used to compensate for the thickness of the third buffer layer 223, and when the second buffer layer 222 is too thin, the fourth buffer layer 224 and/or the fifth buffer layer 225 may be used to compensate for the thickness of the second buffer layer 222. Since the more layers within the buffer layers 22, the more likely it is that the growth efficiency of the buffer layer 22 will be affected, the number of layers of the buffer layers 22 may be 3, 4, or 5 layers.

In the exemplary implementation, continuing to refer to FIG. 1, the first semiconductor layer 20 may further include a nucleation layer 21, which is located on the substrate 10, and the buffer layers 22 are located on a side of the nucleation layer 21 away from the substrate 10. The nucleation layer 21 may affect parameters such as crystal quality, surface topography, and electrical properties of the heterojunction material above it. The nucleation layer 21 varies with different materials of the substrate 10 and mainly serves to match the semiconductor material layers in the substrate 10 and the heterojunction structure. In the present disclosure, the nucleation layer 21 may be formed by high-temperature AlN or low-temperature GaN, which is mainly used to convert the initial three-dimensional growth mode of the buffer layers 22 to a two-dimensional growth mode.

The present disclosure also provides a semiconductor device including an epitaxial structure 100 as described hereinbefore. The above semiconductor device, which can be manufactured by the epitaxial structure 100 as described hereinbefore, thus helps to obtain better device leakage and pinch-off characteristics and improve the sub-threshold characteristics of the device and ensure the reliability of the device. For instance, the source, gate, and drain may continue to be formed on the epitaxial structure 100 described above to obtain a field effect transistor with better performance.

The present disclosure further provides a method of manufacturing an epitaxial structure 100 of a semiconductor device, wherein the structure of the epitaxial structure 100 is illustrated by FIG. 1. The method of manufacturing includes the following steps:

S1: providing a substrate; and

S2: forming a first semiconductor layer 20 on the substrate 10, the first semiconductor layer 20 including buffer layers 22, the buffer layers 22 at least including a first buffer layer 221, a second buffer layer 222, and a third buffer layer 223 which are arranged in layers, and the second buffer layer 222 being located between the first buffer layer 221 and the third buffer layer 223, wherein the buffer layers 22 are doped with iron impurities which are doped in the second buffer layer 222.

In the above-mentioned method of manufacturing, in forming the buffer layers 22, the first buffer layer 221, the second buffer layer 222 and the third buffer layer 223 may be formed in three stages, and the iron impurities are doped in the second buffer layer 222, and the concentration of iron impurities of the second buffer layer 222 is made to satisfy the first preset range, so that on the one hand, this helps to achieve a high resistance of the buffer layers 22 such that the device obtains better leakage and pinch-off characteristics, and on the other hand, iron impurities are distributed in a suitable concentration range in the buffer layer in the middle, while the buffer layers near the substrate 10 and the second semiconductor layer 30 have almost no or only very little iron impurities, helping to improve the crystal quality of the buffer layers 22, and at the same time, this also helps to improve the drain induced barrier lowering (DIBL) effect of the device and trailing effect of the iron impurities, which thus may improve the sub-threshold characteristics of the device and ensure the reliability of the device.

In an exemplary implementation, step S2 specifically includes:

S210: epitaxially growing a nucleation layer 21 on the substrate 10.

The nucleation layer 21 may be formed by high-temperature AN or low-temperature GaN, which is mainly used to convert the initial three-dimensional growth mode of the buffer layers 22 to a two-dimensional growth mode.

S220: epitaxially growing the first buffer layer 221 on a side of the nucleation layer 21 away from the substrate 10.

Specifically, the epitaxial growth process can be used to keep the concentration of carbon impurities in the first buffer layer 221 in a lower range, thus helping to improve the quality of the subsequent crystal growth of the buffer layers.

S230: epitaxially growing the second buffer layer 222 on a side of the first buffer layer 221 away from the nucleation layer 21, while co-doping iron impurities and carbon impurities into the second buffer layer 222, wherein concentration of carbon impurities of the second buffer layer 222 satisfies a second preset range, and the concentration of carbon impurities of the second buffer layer 222 is less than the concentration of iron impurities of the second buffer layer 222.

Specifically, use of a combination of iron impurities and carbon impurities is more helpful in achieving the required high resistance of the buffer layers 22.

S240: epitaxially growing the third buffer layer 223 on a side of the second buffer layer 222 away from the first buffer layer 221.

Specifically, the epitaxial growth process can be used to keep the concentration of carbon impurities in the third buffer layer 223 in a lower range, thereby helping to improve the crystal quality of the buffer layers 22.

Further, step S230 further includes forming the second buffer layer 222 by the epitaxial process while controlling the concentration of carbon impurities of the second buffer layer 222 to be greater than or equal to the concentration of carbon impurities of the first buffer layer 221. Step S240 further includes forming the third buffer layer 223 by the epitaxial process while controlling the concentration of carbon impurities of the third buffer layer 223 to be less than the concentration of carbon impurities of the second buffer layer 222. Making the concentrations of carbon impurities of the first buffer layer 221, the second buffer layer 222, and the third buffer layer 223 satisfy the above relationship is conducive to achieve high resistance of the buffer layers 22 while effectively improving the crystal quality of the buffer layers 22, thus ensuring the performance reliability of the device.

The technical features of the above-described embodiments can be combined arbitrarily. For the sake of brevity, all possible combinations of the technical features in the above embodiments are not described. However, as long as there is no contradiction in the combination of these technical features, it should be regarded as the scope described in this description.

The above-mentioned embodiments only represent several implementations of the present disclosure, and the descriptions thereof are specific and detailed, but should not be construed as a limitation on the scope of the disclosure. It should be pointed out that for those skilled in the art, without departing from the concept of the present disclosure, several modifications and improvements can be made, which all belong to the protection scope of the present disclosure. Therefore, the protection scope of the present disclosure patent shall be subject to the appended claims.

In the claims:

1. An epitaxial structure of a semiconductor device, the structure comprising:
a substrate; and
a first semiconductor layer located on the substrate, the first semiconductor layer comprising buffer layers, the buffer layers at least comprising a first buffer layer, a second buffer layer, and a third buffer layer which are arranged in layers, and the second buffer layer located between the first buffer layer and the third buffer layer;
wherein the second buffer layer is doped with iron impurities, and wherein the first buffer layer and the third buffer layer are not actively doped with iron impurities.

2. The epitaxial structure according to claim 1, wherein the second buffer layer is further doped with carbon impurities, and concentration of carbon impurities of the second buffer layer is less than concentration of iron impurities of the second buffer layer.

3. The epitaxial structure according to claim 2, wherein the concentration of iron impurities of the second buffer layer satisfies a first preset range, wherein the first preset range is 10¹⁶ cm⁻³˜5·10¹⁸ cm⁻³, wherein the concentration of carbon impurities of the second buffer layer satisfies a second preset range, and wherein the second preset range is 10¹⁶ cm⁻³˜10¹⁷ cm⁻³.

4. The epitaxial structure according to claim 1, wherein a thickness of the second buffer layer is ^{d}^{₂}, and wherein 200 nm≤^{d}^{₂}≤800 0nm.

5. The epitaxial structure according to claim 2,
wherein the first buffer layer is located on a side of the second buffer layer close to the substrate, and wherein the third buffer layer is located on a side of the second buffer layer close to a second semiconductor layer;
wherein the first buffer layer has carbon impurities, and wherein concentration of carbon impurities of the first buffer layer is less than or equal to the concentration of carbon impurities of the second buffer layer; and
wherein the third buffer layer has carbon impurities, and wherein concentration of carbon impurities of the third buffer layer is less than the concentration of carbon impurities of the second buffer layer.

6. The epitaxial structure according to claim 5, wherein the concentration of carbon impurities of the first buffer layer is less than or equal to 10 ¹⁷ cm⁻³, wherein the concentration of carbon impurities of the second buffer layer is greater than or equal to 10 ¹⁶ cm⁻³ and less than or equal to 10 ¹⁷ cm⁻³, and wherein the concentration of carbon impurities of the third buffer layer is less than or equal to 5·10¹⁶ cm⁻³.

7. The epitaxial structure according to claim 5, wherein the thickness of the third buffer layer is ^{d}^{₃}, wherein 200 nm≤^{d}^{₃}≤500 nm, wherein the thickness of the first buffer layer is ^{d}^{₁}, and wherein 200 nm≤^{d}^{₁}≤800 nm.

8. The epitaxial structure according to claim 1, wherein the concentration of iron impurities in the first buffer layer is substantially 0, and wherein the concentration of iron impurities in the third buffer layer is less than 10¹⁶ cm⁻³.

9. The epitaxial structure according to claim 8, wherein the concentration of iron impurities in the third buffer layer is substantially 0.

10. A semiconductor device comprising the epitaxial structure according to claim 1.

11. A method of manufacturing an epitaxial structure of a semiconductor device, the method comprising:
providing a substrate;
forming a first semiconductor layer on the substrate, the first semiconductor layer comprising buffer layers, the buffer layers at least comprising a first buffer layer, a second buffer layer, and a third buffer layer which are arranged in layers, and the second buffer layer located between the first buffer layer and the third buffer layer, wherein the second buffer layer is doped with iron impurities, wherein the first buffer layer and the third buffer layer are not actively doped with iron impurities, and wherein a concentration of iron impurities of the second buffer layer satisfies a first preset range; and
forming a second semiconductor layer on a side of the first semiconductor layer opposite the substrate, wherein a conductive channel is formed in the second semiconductor layer.

12. The method of manufacturing according to claim 11, wherein forming a first semiconductor layer on the substrate comprises:
epitaxially growing a nucleation layer on the substrate;
epitaxially growing the first buffer layer on a side of the nucleation layer opposite the substrate;
epitaxially growing the second buffer layer on a side of the first buffer layer opposite the nucleation layer, while co-doping iron impurities and carbon impurities into the second buffer layer; wherein concentration of carbon impurities of the second buffer layer is less than the concentration of iron impurities of the second buffer layer; and
epitaxially growing the third buffer layer on a side of the second buffer layer opposite the first buffer layer.

13. The method of manufacturing according to claim 11, wherein of forming the buffer layers comprises:
turning off an iron source when the first buffer layer is formed, so that the concentration of iron impurities in the first buffer layer is substantially 0;
turning on the iron source and controlling a flow rate when the second buffer layer is formed so that the concentration of iron impurities in the second buffer layer is 10¹⁶ cm⁻³˜5·10¹⁸ cm⁻³; and
turning off the iron source when the third buffer layer is formed, so that the concentration of iron impurities in the third buffer layer is less than 10¹⁶ cm⁻³.

14. The method of manufacturing according to claim 13, wherein the concentration of iron impurities in the third buffer layer is substantially 0.
